(19) United States
(12) Patent Application Publication
(10) Pub. No.: US 2019/0280137 A1
(43) Pub. Date: Sep. 12, 2019

(54) PREFORMED MULTILAYER REFLECTIVE SHEET FOR PHOTOVOLTAIC MODULE AND PRODUCTION METHOD

(71) Applicant: Coveme S.p.A, Gorizia (IT)

(72) Inventors: Luigi MARRAS, Medea (IT); Matteo Racchi, Varmo (IT)

(21) Appl. No.: 16/289,898

(22) Filed: Mar. 1, 2019

(30) Foreign Application Priority Data
Mar. 7, 2018 (IT) 102018000003348

(51) Int. Cl. H01L 31/049; H01L 31/054; H01L 31/048; H01L 31/18; B32B 7/12; B32B 27/36; B32B 27/08

(52) U.S. Cl. CPC H01L 31/049; H01L 31/0547; H01L 31/0488; H01L 31/18; B32B 2457/12; B32B 27/36; B32B 27/08; B32B 2255/10; B32B 7/12

(57) ABSTRACT

A preformed multilayer sheet which has a plurality of openings. These openings allow the light coming from the lower side of the preformed multilayer sheet to partially reach the upper side of the preformed multilayer sheet. The preformed multilayer sheet internally comprises a reflecting layer facing upwards, which therefore makes it possible to reflect the light incident on it and coming from the upper part of the preformed multilayer sheet upwards. Provided is a photovoltaic module which is able to absorb light from both a front and a back side. The preformed multilayer sheet is installed in the back part of the photovoltaic module. The reflecting layer is able to efficiently allow the light coming from below to reach the photovoltaic cells and to reflect the light coming from the interspaces upwards.

### FIELD OF THE INVENTION

The present invention relates to the field of photovoltaic modules. In particular, the present invention relates to the field of reflective sheets for photovoltaic modules configured so as to absorb the light coming from both an upper side and from a side below the same. Furthermore, the present invention relates to a method for producing such reflective sheets for photovoltaic modules.

### BACKGROUND OF THE INVENTION

The basic structure of photovoltaic modules consists of groups of solar cells connected together in series or in parallel and inserted between an upper layer typically made of glass and directly exposed to the sun, and a lower layer. The lower layer performs a multiplicity of functions. It ensures the solar cells' protection from environmental agents, while simultaneously preventing the oxidation of the electrical connections. For example, it prevents moisture, oxygen and other factors related to weather conditions from damaging the cells and electrical connections.

For constructive needs, there is normally an interspace between one cell and the other that separates the same. The presence of this interspace implies that the useful surface on which the solar radiation can be captured coincides with the sum of the front surfaces of each of the cells contained within the photovoltaic module and is therefore smaller than the frontal area of the photovoltaic module itself. This is due to the fact that part of the module's surface is occupied by the interspaces between the various cells. Therefore, to increase the amount of radiation captured by the photovoltaic module, a lower white layer is often installed which is therefore reflective and reflects the light coming from the interspaces upwards. This reflected light can be partly captured by the front surface of the photovoltaic module or, in the case of two-sided modules, on the back side of the cells.

To allow the photovoltaic module to absorb the diffused radiation coming from the back of the photovoltaic module, two-sided photovoltaic modules are often used to absorb the light coming from both the front and the back of the photovoltaic module. To obtain this useful effect, the lower layer must allow light to pass and therefore this layer is normally made of glass or a transparent-type backsheet is used. However, this solution is not currently compatible with the presence of a reflective material such as the one described above. This is because a reflective material is adapted to reflect the greatest possible amount of incident radiation while a transparent material is adapted to transmitting the greatest possible amount of incident radiation, and the two physical characteristics are not combinable with each other. Therefore it would be best to have a photovoltaic module capable of absorbing both the diffused radiation coming from the back side and the light coming from the front side which passes through the interspaces between the cells.

Reflective sheets comprising openings are known from the prior art, which are installed between the backsheet and the photovoltaic cells. However, such installation is particularly difficult and demanding since a further step must be added to the installation process of the photovoltaic module, consisting precisely in the installation of such a reflective sheet below the photovoltaic cells and above the backsheet.

The present invention therefore aims to provide a multilayer sheet which is preformed and can be installed directly on a photovoltaic module. Through this preformed multilayer sheet it will be possible to effectively direct both the light coming from the lower side of the preformed multilayer sheet upwards as well as the light coming from the upper part of the preformed multilayer sheet which is reflected upwards from the preformed multilayer sheet.

### SUMMARY OF THE INVENTION

The present invention is based on the concept of providing a preformed multilayer sheet internally comprising a reflective sheet provided with a plurality of openings, wherein said multilayer sheet is configured so as to be placed behind the solar cells.

In the context of the present invention, the terms “above”, “below”, “lower”, “upper”, “high”, “low”, “front” and “back”, where not otherwise specified, refer to the relative location of the various layers when considering a section view of the final architecture of the photovoltaic module wherein the main surface of the photovoltaic module, i.e. the surface directly facing the sun, occupies the highest level.

According to an embodiment of the present invention a preformed multilayer sheet is provided for use in a photovoltaic module comprising: a transparent supporting layer, a reflecting layer comprising a plurality of openings, and a transparent insulating layer; wherein the reflecting layer is positioned between the transparent supporting layer and the transparent insulating layer. Thanks to the fact that it comprises a plurality of openings, the reflective surface is able to both effectively allow light coming from the lower side to reach the upper side as well as to reflect the light coming from the upper side upwards, which affects the reflecting layer. This configuration therefore makes it possible to direct the light coming from the lower side upwards and pass through the openings, as well as the light coming from the upper side which is reflected by the reflecting layer. Such openings can for example be openings in a regular grid. Moreover, having a multilayer sheet which is preformed is particularly advantageous, as it makes it possible to easily apply this sheet to a photovoltaic module. Furthermore, positioning the reflecting layer between two layers allows the reflecting layer to be protected from external agents. This sheet can, for example, be supplied in ready-for-use sheets or even for example in reels. This solution is also more advantageous than when the reflecting layer is placed above the other two layers. This is due to the fact that according to the present embodiment, it is possible to have a homogeneous surface in order to be then, for example, effectively applied to an external element such as glass in the case of a glass-glass photovoltaic panel or an encapsulating layer when the preformed multilayer sheet acts as a backsheet in a glass-backsheet photovoltaic module. On the other hand, a homogeneous surface would not be obtained if an upper surface was occupied by the reflecting layer.

According to an embodiment of the present invention, a preformed multilayer sheet is provided wherein the supporting layer comprises at least one among PET, PVF and PVDF. The use of PET is particularly advantageous as it can be printed on very easily. The use instead of fluorinated materials such as PVF and PVDF is particularly advantageous, as these materials do not require an external protective coating. The use of any of these materials is also particularly advantageous in that it makes it possible to provide such a preformed multilayer sheet, for example, in a reel and to be able to easily apply such a sheet even on already existing photovoltaic modules, such as on pre-existing photovoltaic modules of the glass-glass type.

According to an embodiment of the present invention, a preformed multilayer sheet is provided wherein the supporting layer has a thickness in the range from 30 to 75 μm, preferably equal to 50 μm. This solution is particularly advantageous because it makes it possible to have a supporting layer of a thickness which guarantees being able to print above it.

According to an embodiment of the present invention, a preformed multilayer sheet is provided further comprising an encapsulating layer positioned above the insulating layer so as to allow a coupling of the preformed multilayer sheet with the photovoltaic cells. This solution is particularly advantageous, as it makes it possible to have a preformed multilayer sheet capable of both insulating and being coupled to other elements thanks to the presence of the encapsulation. In fact, the presence of the transparent encapsulating layer makes it possible to couple this sheet to other elements of a photovoltaic module, such as for example the lower glass in the case of a glass-glass type photovoltaic module.

According to an embodiment of the present invention, a preformed multilayer sheet is provided wherein the encapsulating layer comprises at least one among EVA, LDPE and PP and/or has a thickness in the range from 50 μm to 100 μm. This solution is particularly advantageous since having a transparent encapsulating layer such as EVA and/or LPDE makes it possible to optimize the adhesion of the multilayer structure to other components of the photovoltaic module.

According to an embodiment of the present invention, a preformed multilayer sheet is provided wherein the insulating layer comprises PET and/or has a thickness in the range from75 μm to 350 μm, more preferably equal to 125 μm. This solution is particularly advantageous in that it makes it possible to have an insulating layer able to electrically insulate that which is placed above it from that which is placed below it. In the case of a preformed multilayer sheet applied to a glass-glass type photovoltaic module, the thickness of the insulating layer can also have lower values or even be completely absent, as the back glass of the glass-glass type photovoltaic module alone is able to provide insulation.

According to an embodiment of the present invention, a preformed multilayer sheet is provided wherein the reflecting layer has a thickness greater than 6 μm; more preferably equal to 20 μm. This arrangement makes it possible to both effectively reflect a large part of the radiation incident on the reflective surface upwards and to be able to advantageously form such a reflective surface by, for example, the “roll-to-roll” technique. In fact, even if from a theoretical point of view it would be more advantageous to have an even greater thickness to obtain a better degree of reflection of the reflecting layer, this layer is preferably less than 20 μm in order to avoid high construction costs.

According to an embodiment of the present invention, a preformed multilayer sheet is provided wherein a protective outer coating is positioned on the lower surface of the transparent supporting layer, preferably comprising an acrylic material charged with filtering and stabilizing particles configured to allow filtering of the ultraviolet rays. This solution is particularly advantageous as it makes it possible to have a protective coating such as a “hard coat” able to protect, for example, the layers positioned above from the UV rays which cause yellowing, thus making it a UV filter.

According to an embodiment of the present invention, a preformed multilayer sheet is provided wherein the preformed multilayer sheet is a backsheet for a glass-backsheet type photovoltaic module. The presence of the backsheet in the back makes it possible to have an extremely light lower layer which can at the same time guarantee the long life of the photovoltaic panel, protecting the photovoltaic cells from humidity, atmospheric agents, chemical attacks and ensuring total electrical insulation. Moreover, this backsheet could also be a back-contact backsheet.

According to an embodiment of the present invention, a preformed multilayer sheet is provided wherein the preformed multilayer sheet is a multilayer structure to be applied to the lower surface of a glass-glass type photovoltaic module by means of adhesive, with the adhesive being placed on the upper surface of the preformed multilayer sheet. This solution is particularly advantageous as it makes it possible to apply this preformed multilayer sheet after the photovoltaic module has been assembled, making it adhere to the lower glass with the adhesive. Moreover, this solution also makes it possible to change the sheet without having to open the photovoltaic module. This solution makes it possible to use a standard structure such as a glass-glass type module made with a widely developed method. The use of a glass-glass type module also ensures high cell life thanks to a high level of protection. Glass-glass also makes it possible to obtain aesthetically beautiful photovoltaic modules that are widely used in the so-called BIPV (Building Integrated Photo Voltaic). This solution is also particularly advantageous because it makes it possible to avoid making changes to the already widely-developed production method of the glass-glass type module since the reflective surface located beneath the back glass can be applied at a later stage with respect to the construction of the module itself.

According to an embodiment of the present invention, a photovoltaic module is provided comprising double-sided photovoltaic cells; the photovoltaic module further comprising a preformed multilayer sheet according to an embodiment of the present invention; the preformed multilayer sheet being positioned behind the photovoltaic cells in order to reflect the light passing through the interspaces formed between the photovoltaic cells and so that the openings allow the light coming from the back to reach the photovoltaic cells. This configuration is particularly advantageous in that it makes it possible to effectively capture the light coming from the back side, which after passing through both the openings of the reflective surface and the transparent layer reaches the back of the cells. At the same time, thanks to the reflecting layer, this combination makes it possible to efficiently reflect the radiation coming from the front side and passing through the interspaces upwards.

According to a further embodiment of the present invention, a photovoltaic module is provided wherein the openings are located at the photovoltaic cells. This arrangement makes it possible to optimize the amount of diffused light coming from the back part of the photovoltaic module able to reach the back part of the photovoltaic cells. In the same way this solution is particularly advantageous since the reflective surface is at the interspaces and therefore the radiation passing through the interspaces can thus be effectively reflected upwards. For example, the openings can be centred with respect to the photovoltaic cells.

According to a further embodiment of the present invention, a photovoltaic module is provided wherein the shape of the openings corresponds to the shape of the photovoltaic cells. This solution is particularly advantageous in that it makes it possible to have an optimal shape of the reflecting surface able to position itself exactly at the interspaces formed between two adjacent cells and efficiently reflect the light coming from said interspaces. For example, if the cells have a rectangular shape, there will be rectangular openings.

According to a further embodiment of the present invention, a photovoltaic module is provided wherein the number of openings corresponds to the number of photovoltaic cells. This solution is particularly advantageous in that it is thus possible to have a reflective surface which perfectly corresponds to the shape of the interspaces and is therefore capable of reflecting as much light as possible.

According to a further embodiment of the present invention, a photovoltaic module is provided wherein the openings have a width comprised between the width of each of the cells minus 14 mm and the width of each of the cells, more preferably comprised between the width of each of the cells minus 6 mm and the width of each of the cells minus 1 mm; even more preferably equal to the width of each of the cells minus 2 mm. This arrangement is particularly advantageous as it makes it possible to optimize the amount of radiation captured by the photovoltaic cells.

According to a further embodiment of the present invention, a photovoltaic module is provided wherein the photovoltaic module is a glass-glass type photovoltaic module comprising a front glass and a back glass, wherein the photovoltaic cells are placed below the front glass and above the back glass; wherein the preformed multilayer sheet is a multilayer structure applied to the lower surface of the back glass by means of adhesive placed on the upper surface of the insulating layer. This solution is particularly advantageous as it makes it possible to apply this preformed multilayer sheet after the photovoltaic module has been assembled, making it adhere to the lower glass with the adhesive. Moreover, this solution also makes it possible to change the sheet without having to open the photovoltaic module. This solution makes it possible to use a standard structure such as a glass-glass type module made with a widely developed method.

According to a further embodiment of the present invention, a photovoltaic module is provided wherein the photovoltaic module is a glass-backsheet type photovoltaic module comprising a front glass; wherein the preformed multilayer sheet is the backsheet of the photovoltaic module, wherein the photovoltaic cells are placed below the front glass and above the preformed multilayer sheet. This solution is particularly advantageous in that it makes it possible to have a backsheet that is capable of both insulation and therefore having the typical characteristics of a normal backsheet, and is also capable of reflecting the light coming from the interspaces present between the various cells upwards.

According to a further embodiment of the present invention, a method is provided for producing a preformed multilayer sheet to be used in a photovoltaic module comprising double-sided cells, the method comprising the following steps:
a) providing a transparent layer,
b) providing a reflecting layer comprising a plurality of openings,
c) providing a transparent insulating layer,

wherein the reflecting layer is positioned between the supporting layer and the insulating layer.

Thanks to the fact that it comprises a plurality of openings, the reflective surface is able to effectively allow light coming from the lower side to reach the upper side as well as to reflect the light coming from the upper side upwards, which affects the reflecting layer. This configuration therefore makes it possible to direct the light coming from the lower side upwards and pass through the openings, as well as the light coming from the upper side which is reflected by the reflecting layer. Such openings can for example be openings in a regular grid. Moreover, having a multilayer sheet which is preformed is particularly advantageous, as it makes it possible to easily apply this sheet to a photovoltaic module.

According to a further embodiment of the present invention, a production method of a preformed multilayer sheet is provided wherein the reflecting layer is made by printing on the upper surface of the supporting layer. This solution is particularly advantageous when the transparent supporting layer is made of PET. This is because it is particularly simple to print on a PET surface. Moreover, the fact that printing is carried out on the reflecting layer is particularly advantageous as it makes it possible to have high precision in the positioning of the reflecting surface and makes it possible to have a perfectly homogeneous reflective surface.

According to a further embodiment of the present invention, a production method of a preformed multilayer sheet is provided wherein the reflecting layer is made by printing on the lower surface of the transparent insulating layer. This solution is usually used when the transparent supporting layer is not made of PET; for example when the transparent supporting layer is made of PVF or PVDF. Moreover, the fact that printing is carried out on the reflecting layer is particularly advantageous as it makes it possible to have high precision in the positioning of the reflecting surface and makes it possible to have a perfectly homogeneous reflective surface.

According to a further embodiment of the present invention, a production method of a preformed multilayer sheet is provided wherein the reflecting layer is produced by means of “roll-to-roll” or rotary screen printing. Such printing techniques are particularly advantageous as they make it possible to obtain high printing thicknesses and better performance, which implies having a high degree of reflection; however, they have relatively high costs.

According to a further embodiment of the present invention, a production method of a preformed multilayer sheet is provided wherein the reflecting layer is produced by means of gravure printing or flexography. Such printing techniques are particularly advantageous as they allow a particularly high production speed and particularly low costs. However, it is difficult to reach high thicknesses with such techniques, which therefore imply having a reflecting layer with a lower degree of reflection.

According to a further embodiment of the present invention, a production method of a preformed multilayer sheet is provided wherein the reflecting layer is printed with a thickness greater than 6 μm; more preferably equal to 20 μm. This arrangement makes it possible to both effectively reflect a large part of the incident radiation on the reflecting layer upwards and to apply this surface by means of the “roll-to-roll” technique.

According to a further embodiment of the present invention, a production method of a photovoltaic module comprising double-sided photovoltaic cells is provided; the method includes the following steps:
d) providing a preformed multilayer sheet using a method according to an embodiment of the present invention;
e) positioning the preformed multilayer sheet behind the photovoltaic cells in order to reflect the light passing through the interspaces between the photovoltaic cells and so that the openings allow the light coming from the back to reach the photovoltaic cells.

This method makes it possible to produce a photovoltaic module able to effectively capture the light coming from the back side, which after passing through both the openings of the reflecting layer and the transparent layer, reaches the back of the cells. At the same time, this method makes it possible to produce a photovoltaic module which is able to efficiently reflect the radiation coming from the front side and passing through the interspaces upwards thanks to the reflecting layer.

According to a further embodiment of the present invention, a production method of a photovoltaic module is provided wherein the openings are provided at the photovoltaic cells. The positioning of the openings at the photovoltaic cells makes it possible to optimize the amount of diffused light coming from the back part of the photovoltaic module able to reach the back part of the photovoltaic cells. In the same way this solution is particularly advantageous since the reflecting surface is at the interspaces and therefore the radiation passing through the interspaces can thus be effectively reflected upwards. For example, the openings can be centred with respect to the photovoltaic cells.

According to a further embodiment of the present invention, a production method of a photovoltaic module is provided wherein the photovoltaic module is a glass-glass type photovoltaic module wherein the preformed multilayer sheet is provided after the photovoltaic module has been formed. This solution makes it possible to use a standard structure such as a glass-glass type module made with a widely developed method. The use of a glass-glass type module also ensures high cell life thanks to a high level of protection. Glass-glass also makes it possible to obtain aesthetically beautiful photovoltaic modules that are widely used in the so-called BIPV (Building Integrated Photo Voltaic). This solution is also particularly advantageous because it makes it possible to avoid making changes to the already widely-developed production method of the glass-glass type module since the preformed multilayer surface located beneath the back glass can be applied at a later stage with respect to the construction of the module itself.

According to a further embodiment of the present invention, a production method of a photovoltaic module is provided wherein the openings are preferably provided with a width comprised between the width of the cell minus 14 mm and the width of the cell; more preferably comprised between the width of the cell minus 6 mm and the width of the cell minus 1 mm; even more preferably equal to the width of the cell minus 2 mm. This arrangement is particularly advantageous as it makes it possible to optimize the amount of radiation captured by the photovoltaic cells.

According to a further embodiment of the present invention, a production method of a photovoltaic module is provided wherein the reflecting layer is provided after the photovoltaic module has been formed. This solution is particularly advantageous because it makes it possible to avoid making changes to the widely-developed production method of the photovoltaic module. At the same time, the reflective surface can therefore also be applied to pre-existing photovoltaic modules.

According to a further embodiment of the present invention, a production method of a photovoltaic module is provided wherein the photovoltaic module is a glass-backsheet type photovoltaic module, wherein the preformed multilayer sheet is provided as a backsheet. The presence of the backsheet in the back makes it possible to have an extremely light lower layer which can at the same time guarantee the long life of the photovoltaic panel, protecting the photovoltaic cells from humidity, atmospheric agents, chemical attacks and ensuring total electrical insulation.

### BRIEF DESCRIPTION OF THE DRAWINGS

The present invention is described with reference to the accompanying drawings in which the same reference numbers and/or marks indicate the same parts and/or similar parts and/or corresponding parts of the system.

FIG. 1 diagrammatically shows a section of a preformed multilayer sheet according to an embodiment of the present invention;

FIG. 2 diagrammatically shows a section of a preformed multilayer sheet positioned in the lower part of a glass-glass type photovoltaic module according to an embodiment of the present invention;

FIG. 3 diagrammatically shows a section of a preformed multilayer sheet positioned as a backsheet in a glass-backsheet type photovoltaic module according to an embodiment of the present invention;

FIG. 4 diagrammatically shows the width of the openings of a glass-glass type photovoltaic module according to an embodiment of the present invention;

FIG. 5 diagrammatically shows the width of the openings of a glass-backsheet type photovoltaic module according to an embodiment of the present invention.

### DETAILED DESCRIPTION OF THE EMBODIMENTS

The present invention is described hereinbelow by making reference to particular embodiments, as illustrated in the accompanying drawings. However, the present invention is not limited to the particular embodiments described in the following detailed description and depicted in the drawings, rather the embodiments described simply exemplify the various aspects of the present invention, the scope of which is defined by the claims. Further modifications and variations of the present invention will be apparent to those skilled in art.

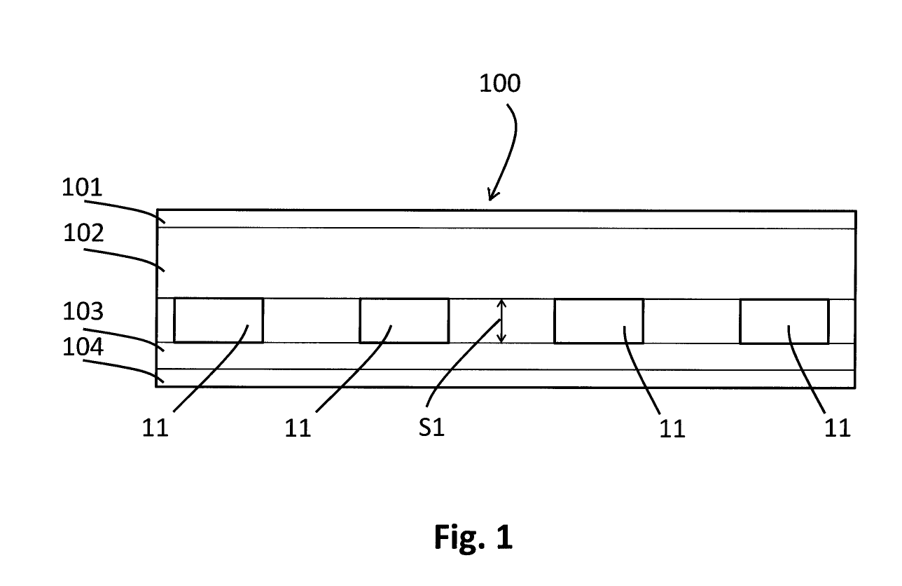

FIG. 1 diagrammatically shows a preformed multilayer sheet 100 according to an embodiment of the present invention. This type of preformed multilayer sheet 100 can be used, for example, for glass-glass type photovoltaic modules 1000 or also for glass-backsheet type photovoltaic modules.

The preformed multi-layer sheet 100 comprises several layers. A first layer is represented by a transparent supporting layer 103. A layer above it is represented by a reflecting layer 11, above which a layer is placed comprising a transparent insulating layer 102 and an encapsulating layer 101 placed above the transparent insulating layer 102.

The supporting layer 103 can be a layer of PET having a thickness of, for example, 50 μm. Alternatively, the transparent supporting layer 103 can be a layer of PVF (fluorinated materials) or PVDF (e.g. Kynar). The use of PVF or PVDF is particularly advantageous, as these materials do not require an external protective coating.

The printing of the reflecting layer 11 can be carried out on the upper surface of the supporting layer 103.

The reflecting layer 11 is configured to reflect the greatest possible amount of light. Therefore it must have a suitable thickness so as to ensure good reflection, considering that the increasing thickness consequently increases the amount of reflected light. A thickness S1 of the reflecting layer 11 less than 10 μm would result in a quantity of reflected light equal to about 65% of the incident light. The reflecting layer 11 preferably has a thickness S1 greater than 10 μm, although to obtain low production costs, having a thickness S1 preferably greater than 6 μm will suffice. More preferably, having a thickness S1 of the reflecting layer 11 equal to 20 μm, a reflection of 80% of the incident light can be obtained. In principle, higher thicknesses can also be made, which therefore reflect a greater amount of incident light, but also increase the production costs of the reflecting layer 11.

The material used for such a reflecting layer 11 can be, for example, a synthetic resin or a mixture. Examples of synthetic resin are, for example, polyester, polyurethane, acrylic, epoxy, silicone or alkyl resins which are preferably charged with white titanium dioxide particles (TiO₂) or other metal oxides such as zinc, silicon, barium or aluminium. The resins can either be of the single-component type or of the two-component type with cross-linking catalysts such as isocyanate.

As described above, an insulating layer 102 is placed above the reflecting layer 11.

The transparent insulating layer 102 is for example represented by an inner layer of transparent PET resistant to hydrolysis. This layer 102 can have a thickness ranging between 75 and 350 μm and is typically used with a thickness of 125 μm.

As described above, an encapsulating layer 101 can be found above this insulating layer 102. This layer 101 can be a layer of primer. The primer is a transparent polyolefin that binds to the encapsulant and can be for example EVA or LDPE (more rarely PP). The thickness of the primer can be around 50-100 μm.

Alternatively, the layer 101 can be represented by a transparent coating layer having a thickness which can vary between 4 μm and 20 μm. The layer 101 can also be represented by a polymeric coating layer which represents an intermediate layer of adhesion by creating an added interface between the underlying polyester 102 and the encapsulating EVA. This polymeric adhesion promoter can be transparent and can have a thickness ranging from 4 μm to 20 μm.

Furthermore, a further layer 104 can be positioned below the transparent supporting layer 103, which can be a protective outer coating, which is also transparent, which acts as an ultraviolet filter thereby protecting the PET. Normally it is an acrylic coating, charged with special filtering particles and stabilizers able to protect the upper layers from the ultraviolet rays that would otherwise cause yellowing in the upper layers.

Among the various layers described above, there can be a structural adhesive for in-line hot rolling having a thickness of around 4-12 μm, adapted to allow the effective adhesion between the layers.

In the example shown in the figure, the reflecting layer 11 is positioned between the transparent insulating layer 102 and the transparent supporting layer 103. However, it is also possible that this reflecting layer 11, when a preformed multilayer sheet 100 having a greater number of layers is present, is positioned in another point.

A thermoadhesive can be applied above the encapsulating layer 101 so as to allow an efficient adhesion of the sheet 100 to an external surface.

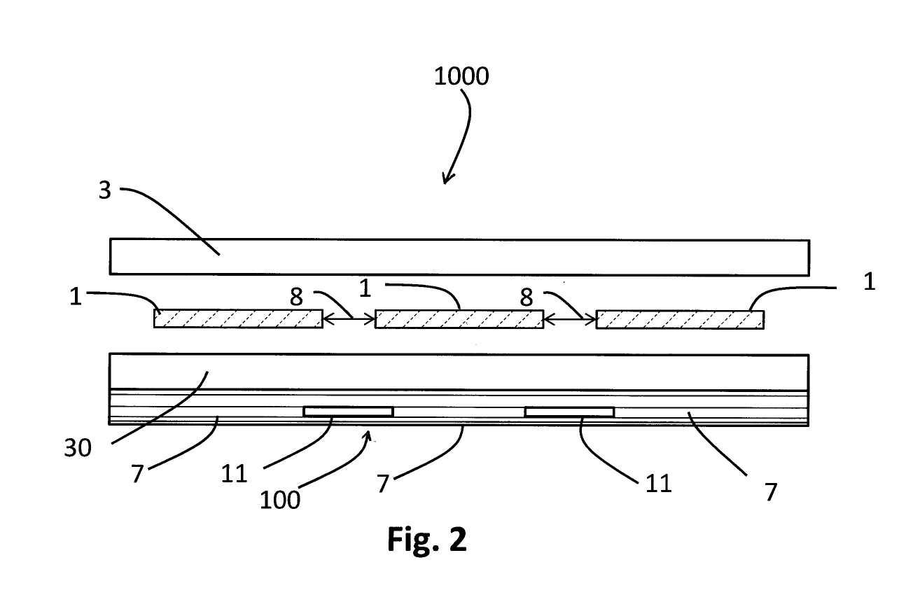

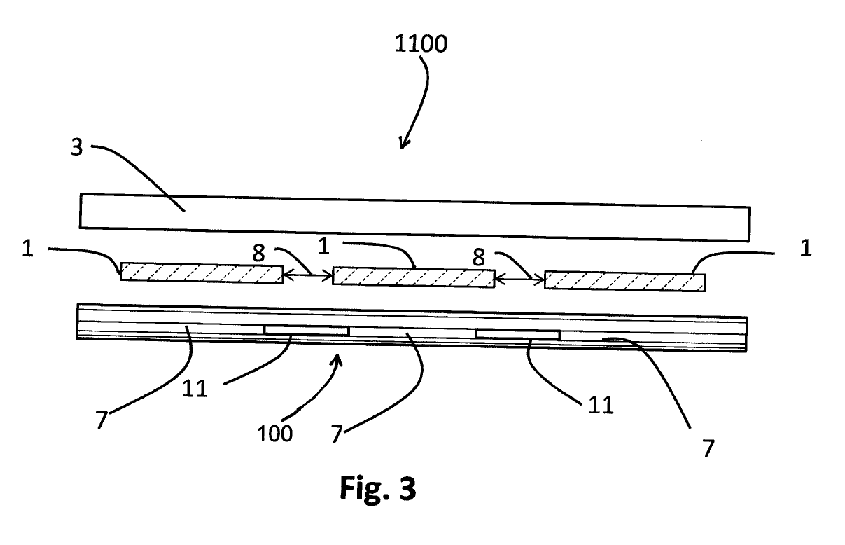

The preformed sheet 100 can be applied to the back surface of the back glass of a glass-glass type photovoltaic module or alternatively act directly as a backsheet in a glass-backsheet type photovoltaic module. With reference to FIGS. 2 and 3, the two alternative uses of such a preformed sheet 100 will be described in detail.

FIG. 2 shows an embodiment of the present invention wherein the preformed multilayer sheet 100 is positioned on the back of a glass-glass type photovoltaic module 1000.

The photovoltaic module 1000 comprises photovoltaic cells 1 and is configured so as to be able to absorb light from a front side and a back side. Therefore, for example double-sided solar cells can be used for this purpose. In the front part of the photovoltaic cells 1, the photovoltaic module 1000 further comprises a front glass 3 in order to protect the photovoltaic cells 1 from external agents and to transmit the solar radiation coming from the front part to the photovoltaic cells 1. The front glass 3 forms the main surface of the photovoltaic module, i.e. the surface that, in use, is turned directly towards the sun. In the back part of the photovoltaic cells 1, the photovoltaic module 1000 has a back glass 30.

As shown in the figure, the preformed multilayer sheet 100 defines the back air side of the photovoltaic module 1000, while the main air side, as described above, is represented by the front glass 3.

For constructive needs, the cells that form a two-dimensional array are distanced from each other and therefore interspaces 8 are formed between them. For example, the width of such interspaces 8 can be around 1-10 mm, more typically it is around 3-5 mm. The interspaces are normally located on both directions in which the array extends and normally have the same widths along each direction.

The photovoltaic module 1000 further comprises a preformed multilayer sheet 100 placed under the back glass 30.

The preformed multilayer sheet 100 comprises a plurality of openings 7 so as to allow the light coming from the back side to reach the photovoltaic cells 1.

As shown in the figure, the openings 7 are located at the photovoltaic cells 1. In particular, the figure shows that the openings 7 are centred with respect to the photovoltaic cells 1. This makes it possible to optimize the amount of diffused light coming from the back part of the photovoltaic module 1000 able to reach the back part of the photovoltaic cells 1.

The reflecting layer 11 of the preformed multilayer sheet 100 is consequently positioned at the interspaces 8 between the photovoltaic cells 1. This is particularly advantageous since in this way the radiation passing between the interspaces 8 can be effectively reflected upwards by the reflecting layer 11.

As shown in the figure, the preformed multilayer sheet 100 is positioned below the back glass 30. This positioning of the preformed multilayer sheet 100 makes it possible to have an easier production method, as it makes it possible to install this preformed multilayer sheet 100 after the production of the photovoltaic module 1000.

The preformed multilayer sheet 100 can be combined with the lower surface of the back glass 30 by, for example, a simple adhesive or a thermoadhesive.

Furthermore, in the case of a glass-glass type photovoltaic module, the insulating layer 102 can have a lower thickness than the one described above. Therefore it can have a thickness less than 50 μm, or even be completely absent. This is because the insulation is already provided by the back glass.

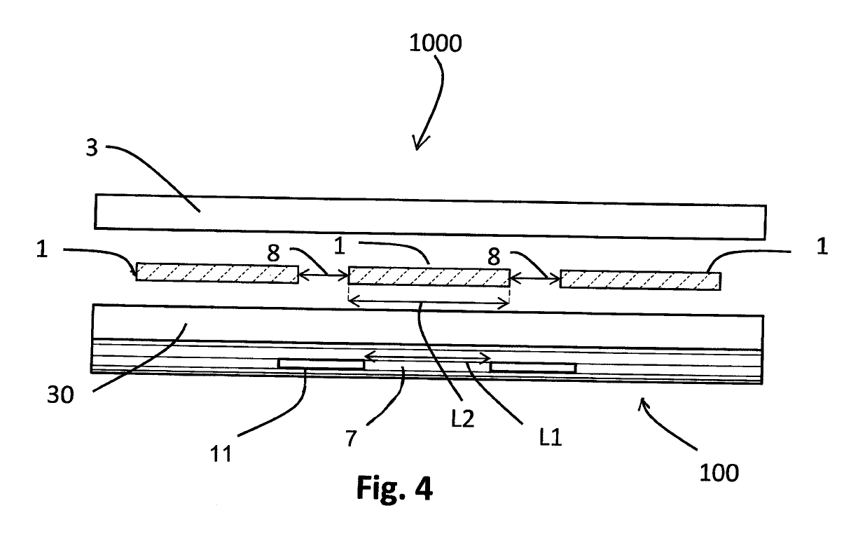

FIG. 4 diagrammatically shows the ratio between the width L1 of the openings 7 with respect to the width L2 of the cells 1 according to an embodiment of the present invention.

By increasing the width L1 of the openings 7, the amount of diffused light coming from the back part and directed to the cells 1 increases accordingly. This increase is due to the fact that it increases the amount of diffused light coming from the back side and able to reach the cells 1. At the same time, however, there is a decrease in the amount of light passing through the interspaces 8 which is reflected upwards. This decrease is due to the fact that the light coming from the front side of the photovoltaic module 1000 passes through the interspaces 8 with different angles of incidence, partially not affecting the reflecting layer 11.

Therefore, by varying the width of the openings, a significant variation of the light radiation captured by the photovoltaic cells 1 was observed. It has been seen that the light radiation captured by the photovoltaic cells reaches optimal values for a width L1 of the openings 7 between the width of the cells L2 minus 14 mm and the width of the cells L2 (L2−14 mm≤L1≤L2). It has been seen that the light radiation captured by the photovoltaic cells reaches even more optimal values for a width L1 of the openings 7 between the width of the cells L2 minus 6 mm and the width of the cells L2 minus 1 mm (L2−6 mm≤L1≤L2−1). More preferably, the width of the openings L1 is equal to the width of the cells L2 minus 2 mm (L1=L2−2 mm).

It is clear that these numbers refer to the particular case described above wherein the interspace between the cells 1 has a thickness around 1-10 mm. In the case wherein the thickness is greater or smaller, the width of the openings will vary from what has been described above.

It is also clear that what is described above applies, in a similar way, to the height of the cells and to the height of the openings (when they are rectangular cells).

In any case, even in the particular case of cells having a shape other than a square or rectangular, such openings 7 will correspond to the particular shape of the cells 1.

FIG. 3 diagrammatically shows a glass-backsheet type photovoltaic module 1100 according to a further embodiment of the present invention.

The photovoltaic module 1100 comprises photovoltaic cells 1 and is configured so as to be able to absorb light from a front side and a back side. Therefore, for example double-sided solar cells can be used for this purpose. In the front part of the photovoltaic cells 1, the photovoltaic module 1100 further comprises a front glass 3 configured to protect the photovoltaic cells 1 from external agents and to transmit the solar radiation coming from the front part to the photovoltaic cells 1. The front glass 3 forms the main surface of the photovoltaic module, i.e. the surface that, in use, is turned directly towards the sun.

In the back part of the photovoltaic cells 1, the photovoltaic module 1100 has a preformed multilayer sheet 100 like the one diagrammatically shown in FIG. 1.

As in the case described above concerning the glass-glass type photovoltaic module, for construction requirements the cells are spaced from each other and therefore interspaces 8 are formed between them. For example, the width of such interspaces 8 can be around 1-10 mm, more typically it is around 3-5 mm.

The reflecting layer 11 of the preformed multilayer sheet 100 comprises a plurality of openings 7 so as to allow the light coming from the back side to reach the photovoltaic cells 1.

As shown in the figure, the openings 7 are located at the photovoltaic cells 1. In particular, the figure shows that the openings 7 are centred with respect to the photovoltaic cells 1. This makes it possible to optimize the amount of diffused light coming from the back part of the photovoltaic module 1100 able to reach the back part of the photovoltaic cells 1.

The reflecting layer 11 is consequently positioned at the interspaces 8 between the photovoltaic cells 1. This is particularly advantageous since the radiation passing between the interspaces 8 can be effectively reflected upwards by the reflecting layer 11.

It can thus be noted that the reflecting layer 11 is simply inserted into a backsheet similar to those commonly used for glass-backsheet type photovoltaic modules.

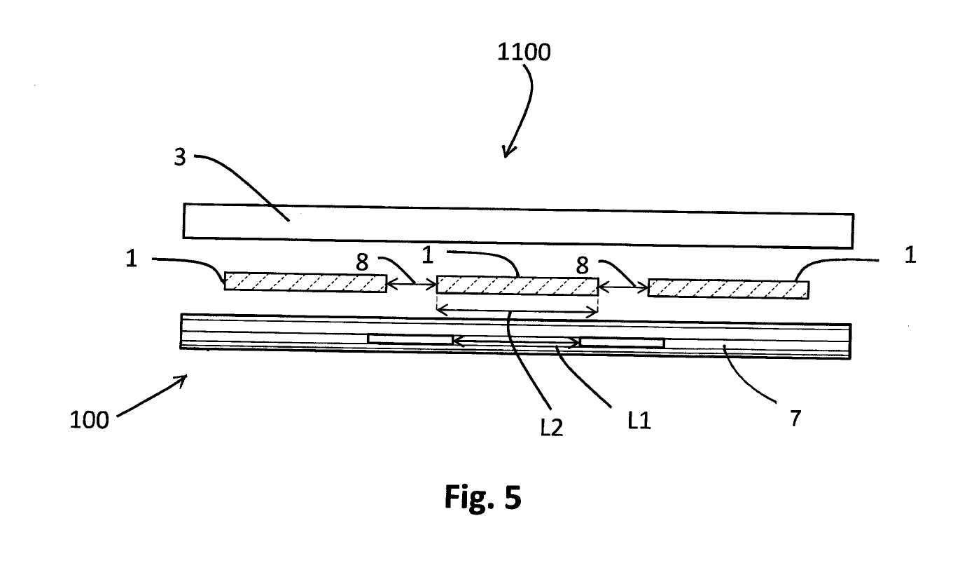

FIG. 5 diagrammatically shows the ratio between the width L1 of the openings 7 with respect to the width L2 of the cells 1 according to an embodiment of the present invention.

By increasing the width L1 of the openings 7, the amount of diffused light coming from the back part and directed to the cells 1 increases accordingly. This increase is due to the fact that it increases the amount of diffused light coming from the back side and able to reach the cells 1. At the same time, however, there is a decrease in the amount of light passing through the interspaces 8 which is reflected upwards. This decrease is due to the fact that the light coming from the front side of the photovoltaic module 1100 passes through the interspaces 8 with different angles of incidence, partially not affecting the reflecting layer 11.

Therefore, also in this case, by varying the width of the openings, a significant variation of the light radiation captured by the photovoltaic cells 1 was observed. It has been seen that the light radiation captured by the photovoltaic cells reaches optimal values for a width L1 of the openings 7 between the width of the cells L2 minus 14 mm and the width of the cells L2 (L2−14 mm≤L1≤L2). It has been seen that the light radiation captured by the photovoltaic cells reaches even more optimal values for a width L1 of the openings 7 between the width of the cells L2 minus 6 mm and the width of the cells L2 minus 1 mm (L2−6 mm≤L1≤L2−1). More preferably, the width of the openings L1 is equal to the width of the cells L2 minus 2 mm (L1=L2−2 mm).

It is clear that these numbers refer to the particular case described above wherein the interspace between the cells 1 has a thickness around 1-10 mm. In the case wherein the thickness is greater or smaller, the width of the openings will vary from what has been described above.

It is also clear that what is described above applies, in a similar way, to the height of the cells and to the height of the openings (when they are rectangular cells).

In any case, even in the particular case of cells having a shape other than a square or rectangular, such openings 7 will correspond to the particular shape of the cells 1.

The production method of a preformed multilayer sheet 100 for a photovoltaic module according to a particular embodiment of the present invention is described below.

The method involves the lamination of a layer of PET 103 which will form the transparent supporting layer described above. A protective layer 104 has been previously placed on the lower part of the supporting layer through, for example, an adhesive.

The protective layer 104 and the supporting layer 103 have the thicknesses described above. Furthermore, the supporting layer 103 can be made of PVF or PVDF instead of PET. In this case, the protective layer 104 can be completely absent.

The production method of the preformed multilayer sheet 100 subsequently comprises printing the reflecting layer 11 directly on the supporting layer 103.

For printing, various techniques such as gravure printing or rotary screen printing can be used, which will be explained later.

Subsequently, an adhesive is spread over the reflecting layer 11. This adhesive has the characteristics described above.

In a subsequent step, the above-described layers are combined with a laminated sheet of PET which corresponds to the insulating layer 102. If the supporting layer 103 is not made of PET, it is preferable that the printing of the reflecting layer 11 is carried out directly on the insulating layer 102.

As described above, when a preformed multilayer sheet 100 is to be made for a glass-glass type photovoltaic module, the insulating layer 102 can also be completely absent. In this case, the adhesive layer described above will be used to adhere the encapsulating layer 101.

After the insulating layer 102 has been adhered to the adhesive, another adhesive will be spread over the insulating layer 102.

After the adhesive has been coated, the encapsulating layer 101 will be adhered above the adhesive and the preformed multi-layer sheet 100 according to a particular embodiment of the present invention is thus ready.

To implement the formation of the reflecting layer in the context of a “roll-to-roll” process, there is a simultaneous need to have a reduced thickness of the reflecting layer to allow for reduced costs using the “roll-to-roll” printing technique and to have a thickness that is not too low in order to ensure good reflection of the incident light.

Therefore the reflecting layer 11 must have an optimized thickness so as to ensure good reflection, considering that the increasing thickness consequently increases the amount of reflected light. A thickness S1 of the reflecting layer 11 less than 10 μm would result in a quantity of reflected light equal to about 65% of the incident light. For this reason the reflecting layer 11 instead has a thickness S1 greater than 10 μm although in many cases, to keep production costs low, it can simply have a thickness S1 preferably greater than 6 μm. More preferably, having a thickness S1 of the reflecting layer 11 equal to 20 μm, a reflection of 80% of the incident light can be obtained.

Therefore, based on the desired thickness of the reflecting layer 11, and depending on budget, different printing techniques will be used.

The least expensive techniques are gravure printing and flexography. These techniques have high production speeds and very low costs. However, they cannot reach high thicknesses of the reflecting layer 11.

For this reason, when a greater thickness S1 is desired in the reflecting layer 11, it is preferable to use “roll-to-roll” or rotary silk-screen printing means. Silk-screen printing allows a greater deposit of ink compared to traditional printing techniques and therefore makes it possible to reach higher thicknesses without reducing printing accuracy.

Alternatively, the reflecting layer can be printed through “rotogravure” printing.

As described above, the reflecting layer 11 according to an embodiment of the present invention is printed directly onto the transparent supporting layer 103. However, if the transparent supporting layer 103 is not made of PET, it is preferable to print the reflecting layer 11 directly on the transparent insulating layer 102 because printing on PET is particularly easy and makes it possible to achieve high precision.

The production method of a photovoltaic module based on a particular embodiment of the present invention is described below. In this case the photovoltaic module can be either a glass-glass type photovoltaic module 1000 or a glass-backsheet type photovoltaic module 1100.

The method comprises the following steps:
d) providing a preformed multilayer sheet 100 with the method described above;
e) positioning the preformed multilayer sheet 100 behind the photovoltaic cells 1 in order to reflect the light passing through the interspaces 8 between the photovoltaic cells 1 and so that the openings 7 allow the light coming from the back to reach the photovoltaic cells 1.

The photovoltaic module can be of the glass-glass type and can be made with known techniques. In this case the preformed multilayer sheet can advantageously be positioned below the back glass of the glass-glass module. This solution is particularly advantageous because it makes it possible to avoid making changes to the widely-developed production method of glass-glass type photovoltaic modules.

Furthermore, the reflective surface can also be applied to pre-existing glass-glass photovoltaic modules.

Alternatively, the preformed multilayer sheet 100 can be used as a backsheet for a glass-backsheet type photovoltaic module 1100. The backsheet, which can be represented by the preformed multilayer sheet 100, can therefore be used in the formation of photovoltaic modules instead of the commonly used backsheets.

In general, the reflecting layer 11 of the preformed multilayer sheet 100 is provided at the interspaces 8 between the cells 1 of the photovoltaic module. For example, if the cells 1 of the photovoltaic module are square and are arranged to form a regular array, the reflecting layer 11 can be formed as a grid placed at the interspaces between the cells.

Although the present invention was described with reference to the embodiments described above, it is apparent to an expert in the field that it is possible to make several modifications, variants and improvements to the present invention in light of the above teaching and within the scope of the appended claims, without departing from the object and the scope of protection of the invention.

For example, even if it has been explicitly described that the reflecting surface 11 in the case of a glass-glass type photovoltaic module 1000 is located below the back glass 30, the reflecting surface 11 can also be placed above the back glass 30.

Moreover, even if it has been described that the preformed multilayer sheet 100 for a glass-backsheet type photovoltaic module 1100 or for a glass-glass type photovoltaic module 1000 is composed of 4 or 3 layers, in some cases the supporting layer 103 and the insulating layer 102 can be represented by a single thicker layer in direct contact with the outer protective coating 104, or by several layers.

Moreover, even if it has been described that the reflecting layer 11 is printed directly on a layer, that is, depending on the case on the supporting layer 103 or on the insulating layer 102, it is also possible that the reflecting layer 11 is pre-printed and applied to the other layers by means of adhesive.

Finally, those fields known by experts in the field were not described to avoid excessively and uselessly overshadowing the invention described.

Accordingly, the invention is not limited to the embodiments described above, but is only limited by the scope of protection of the appended claims.

What is claimed is:

1. A preformed multilayer sheet to be used in a photovoltaic module, preferably in a photovoltaic module comprising double-sided cells, said sheet comprising:
a transparent supporting layer,
a reflecting layer comprising a plurality of openings, and
a transparent insulating layer; wherein
said reflecting layer is positioned between said supporting layer and said insulating layer,
wherein said supporting layer comprises at least one of PET, PVF and PVDF.

2. The preformed multilayer sheet according to claim 1, wherein:
said supporting layer has a thickness between 30 μm and 75 μm.

3. The preformed multilayer sheet according to claim 1, further comprising:
an encapsulating layer positioned above said insulating layer so as to allow a coupling of said preformed multilayer sheet with photovoltaic cells.

4. The preformed multilayer sheet according to claim 3, wherein:
said encapsulating layer comprises at least one of EVA, LDPE and PP, and/or has a thickness between 50 μm and 100 μm.

5. The preformed multilayer sheet according to claim 1, wherein:
said insulating layer comprises PET and/or has a thickness from 75 μm to 350 μm.

6. The preformed multilayer sheet according to claim 1, wherein:
said reflecting layer has a thickness greater than 6 μm.

7. The preformed multilayer sheet according to claim 1, further comprising:
a protective outer coating placed on the lower surface of said transparent supporting layer, preferably comprising an acrylic material charged with filtering and stabilizing particles configured to allow ultraviolet rays to be filtered.

8. The preformed multilayer sheet according to claim 1, wherein:
said preformed multilayer sheet is a backsheet for a photovoltaic module.

9. The photovoltaic module comprising double-sided photovoltaic cells; the photovoltaic module further comprising the preformed multilayer sheet according to claim 1, the preformed multilayer sheet being positioned behind with respect to said photovoltaic cells so that the openings are located at said photovoltaic cells so as to allow light coming from the back to reach said photovoltaic cells and to reflect the light passing through interspaces formed between said photovoltaic cells.

10. The photovoltaic module according to claim 9, wherein:
a shape of the openings corresponds to a shape of said photovoltaic cells.

11. The photovoltaic module according to claim 9, wherein:
the openings have a first width comprised between a second width of each of said photovoltaic cells minus 14 mm and the second width of each of said photovoltaic cells; more preferably comprised between the second width of each of said photovoltaic cells minus 6 mm and the second width of each of said photovoltaic cells minus 1 mm; even more preferably equal to the second width of each of said photovoltaic cells minus 2 mm.

12. The photovoltaic module according to claim 9, wherein:
the photovoltaic module is a glass-glass type photovoltaic module, comprising a front glass and a back glass, wherein said photovoltaic cells are located below said front glass and above said back glass; wherein said preformed multilayer sheet is a multilayer structure applied to the lower surface of said back glass by adhesive placed on an upper surface of said insulating layer.

13. The photovoltaic module according to claim 9, wherein:
the photovoltaic module is a glass-backsheet type photovoltaic module comprising a front glass; wherein said preformed multilayer sheet is a backsheet of the photovoltaic module, wherein said photovoltaic cells are placed below said front glass and above said preformed multilayer sheet.

14. A photovoltaic module comprising double-sided photovoltaic cells; said photovoltaic module further comprising:
a preformed multilayer sheet, said preformed multilayer sheet comprising:
a transparent supporting layer,
a reflecting layer having openings, and
a transparent insulating layer;
wherein said reflecting layer is positioned between said supporting layer and said insulating layer;
said preformed multilayer sheet being positioned behind with respect to said photovoltaic cells so that the openings are located at said photovoltaic cells so as to allow light coming from the back to reach said photovoltaic cells and to reflect the light passing through interspaces formed between said photovoltaic cells;
wherein the photovoltaic module is a glass-glass type photovoltaic module, comprising a front glass and a back glass, wherein said photovoltaic cells are located below said front glass and above said back glass; wherein said preformed multilayer sheet is a multilayer structure applied to a lower surface of said back glass by adhesive placed on an upper surface of said insulating layer.

15. A method for the production of a preformed multilayer sheet to be used in a photovoltaic module, preferably in a photovoltaic module comprising double-sided cells, the method comprising the steps of:
providing a transparent supporting layer,
providing a reflecting layer having openings,
providing a transparent insulating layer,
wherein the reflecting layer is positioned between the transparent supporting layer and the transparent insulating layer, wherein the transparent supporting layer comprises at least one among PET, PVF and PVDF.

16. The method according to claim 15, wherein:
the reflecting layer is made by printing on an upper surface of the transparent supporting layer.

17. The method according to claim 15, wherein:
the reflecting layer is made by printing on a lower surface of the transparent insulating layer.

18. A method for the production of a photovoltaic module comprising double-sided photovoltaic cells, the method comprising the steps of:
providing the preformed multilayer sheet with a method according to claims 15;
positioning the preformed multilayer sheet behind with respect to the double-sided photovoltaic cells so that the openings are positioned at said double-sided photovoltaic cells so as to reflect light passing through interspaces between said double-sided photovoltaic cells and in such a way as to allow the light coming from the back to reach said double-sided photovoltaic cells.

19. The production method of a photovoltaic module according to claim 18, wherein:
said photovoltaic module is a glass-glass type photovoltaic module, wherein the preformed multilayer sheet is provided after the photovoltaic module has been formed.

20. The production method of a photovoltaic module according to claim 18, wherein:
the photovoltaic module is a glass-backsheet type photovoltaic module, wherein the preformed multilayer sheet is provided as a backsheet.
